(19) United States
(12) Patent Application Publication
(10) Pub. No.: US 2015/0286141 A1
(43) Pub. Date: Oct. 8, 2015

(54) Method of Forming Line Pattern on Substrate

(71) Applicant: Top Victory Investments Ltd., Kowloon (HK)

(72) Inventors: Wei-Ting Lin, New Taipei City (TW); Yung-Shin Liou, New Taipei City (TW)

(73) Assignee: Top Victory Investments Ltd., Kowloon (HK)

(21) Appl. No.: 14/243,927

(22) Filed: Apr. 3, 2014

(51) Int. Cl. G03F 7/16

(52) U.S. Cl. CPC G03F 7/16

(57) ABSTRACT

The present invention relates to a method of forming a line pattern on a substrate. The method comprises steps as follows: providing a substrate plate; forming a photoresist pattern on a predetermined surface of the substrate plate; applying a coating film to the predetermined surface of the substrate plate and the photoresist pattern; and removing the photoresist pattern to form the line pattern. The manufacturing process of the invention doesn't require etching. Comparing to the prior art, the invention reduces cost and improves yield rate.

### BACKGROUND OF THE INVENTION

1. Field of the Invention

The present invention relates to a line pattern, and more particularly, to a method of forming the line pattern on a substrate.

2. Description of the Prior Art

Display devices with touch function are getting popular in recent years. Generally, a solution that allows display devices can be controlled by touch is integrating a touch module with a display panel. Mainstream of display devices are liquid crystal displays (LCDs). An LCD comprises a display panel and a backlight module. The backlight module as a surface light source provides light rays to the display panel. The display panel processes the light rays passing through thereof and displays the processed light rays on a display surface thereon which locates on a side of the display panel opposite to the backlight module to form colorful static images or dynamic images. A touch sensing component of a touch module, e.g. a line pattern of a touch sensing circuit, is usually attached to the display surface. Users perform touch control by touching the display panel and stimulating the touch sensing component accordingly.

A method of forming a line pattern in the prior art comprises: applying a coating film to a display surface; applying a photoresist layer to the coating film; exposing and developing the photoresist layer to form a required photoresist pattern; etching the coating film to form the required line pattern; and finally removing the photoresist pattern by a photoresist stripper. Timing of forming the line pattern in a manufacturing process is: first forming the line pattern on a back side of a glass substrate plate which will be utilized for a color filter (the back side will be a display surface of an assembled display panel), and then assembling the display panel; or first assembling the display panel, and then forming the line pattern on the back side of the color filter of the assembled display panel. Wherein, the former has difficulty to practice because most assembled display panels will be further process a thickness reduction since market prefers products being light and thin. The latter has problems that the back side of the color filter of the assembled display panel is usually polluted or scratched during manufacturing process, and etching on a polluted or scratched surface usually has negative affection with regard to completeness of the line pattern caused by pollution or scratches. Such that lines of the line pattern may be cut off, and yield rate of the display panel declines accordingly.

### SUMMARY OF THE INVENTION

According to the shortage of the prior art, the present invention aims to provide a method of forming a line pattern on a substrate, so the method can be applied to a touch display device requiring thickness reduction, and can prevent negative affection with regard to completeness of the line pattern caused by pollution or scratches.

According to the claimed invention, the method of forming the line pattern on the substrate comprises: providing a substrate plate; forming a photoresist pattern on a predetermined surface of the substrate plate; applying a coating film to the predetermined surface of the substrate plate and the photoresist pattern; and removing the photoresist pattern to form the line pattern.

According to an embodiment of the claimed invention, steps of forming the photoresist pattern on the predetermined surface of the substrate plate further comprises: applying a photoresist layer to the predetermined surface; exposing a predetermined area of the photoresist layer; and developing the photoresist layer to form the photoresist pattern.

According to another embodiment of the claimed invention, the photoresist layer includes a negative photoresist material.

According to another embodiment of the claimed invention, a cross section of the photoresist pattern includes a bottom edge and a top edge, the bottom edge is adjacent to the substrate plate and is opposite to the top edge, and a width of the bottom edge is less than that of the top edge. Specifically, a shape of the cross section of the photoresist pattern is an inverted trapezoid.

According to another embodiment of the claimed invention, after applying the coating film to the predetermined surface of the substrate plate and the photoresist pattern, a gap is formed between a first coating film applied to the photoresist pattern and a second coating film applied to the predetermined surface, and a height of the gap corresponds to a thickness of the photoresist pattern.

According to another embodiment of the claimed invention, steps of removing the photoresist pattern to form the line pattern further comprises: using a photoresist stripper to remove the photoresist pattern.

According to another embodiment of the claimed invention, after removing the photoresist pattern, the first coating film applied to the photoresist pattern is accordingly removed, and the second coating film applied to the predetermined surface is left to form the line pattern.

According to another embodiment of the claimed invention, the substrate plate includes a color filter, a liquid crystal layer, and a thin film transistor layer. The liquid crystal layer is sandwiched between the color filter and the thin film transistor layer, and the predetermined surface locates on a side of the color filter opposite to the liquid crystal layer.

According to another embodiment of the claimed invention, the line pattern is a touch sensing component.

The method of forming the line pattern on the substrate of the present invention can be applied to the touch display device requiring thickness reduction. The method can be performed after the display panel has been assembled to form the line pattern. The method prevents negative affection with regard to completeness of the line pattern caused by pollution or scratches on the surface of the substrate plate, since processes thereof do not require etching. Comparing to the prior art, the invention reduces cost and improves yield rate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram of a display panel according to a preferred embodiment of the present invention.

FIG. 2 is the first diagram of steps of forming a line pattern according to the preferred embodiment of the present invention.

FIG. 3 is the second diagram of steps of forming the line pattern according to the preferred embodiment of the present invention.

FIG. 4 is the third diagram of steps of forming the line pattern according to the preferred embodiment of the present invention.

FIG. 5 is the fourth diagram of steps of forming the line pattern according to the preferred embodiment of the present invention.

FIG. 6 is the fifth diagram of steps of forming the line pattern according to the preferred embodiment of the present invention.

### DETAILED DESCRIPTION

The present invention provides a method of forming a line pattern on a substrate. The method can be applied to the substrate, and more specifically to forming the line pattern on a substrate plate. In the embodiment, the line pattern is substantially a touch sensing component, and the substrate plate is substantially a display panel. In other words, the substrate plate with the line pattern is a touch display panel with touch function.

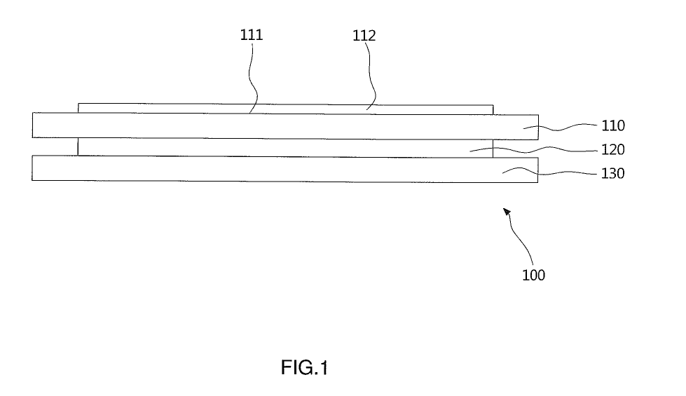

Please refer to FIG. 1. FIG. 1 depicts a display panel 100 according to a preferred embodiment of the present invention. The display panel 100 has touch function and comprises a color filter (CF) 110, a liquid crystal layer 120, a thin film transistor (TFT) layer 130, and a touch sensing component 112. The liquid crystal layer 120 is sandwiched between the color filter 110 and the thin film transistor layer 130. A surface on a side of the color filter 110 opposite to the liquid crystal layer 120 is a display surface 111. The display surface 111 is a predetermined surface utilized for forming the line pattern. The touch sensing component 112, i.e. the line pattern, is attached to the display surface 111.

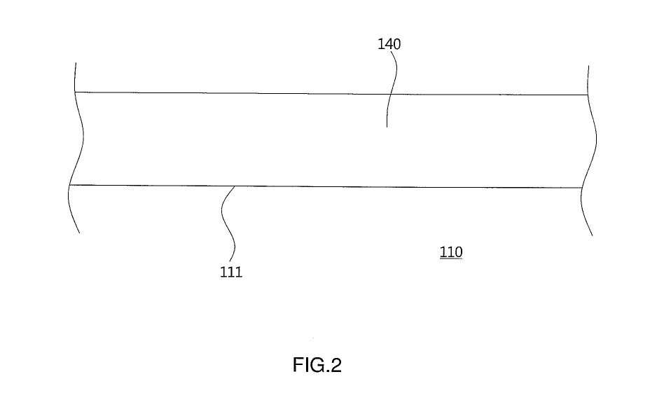

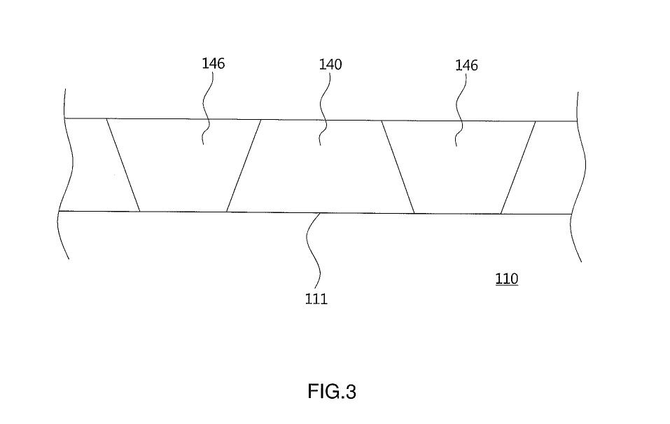

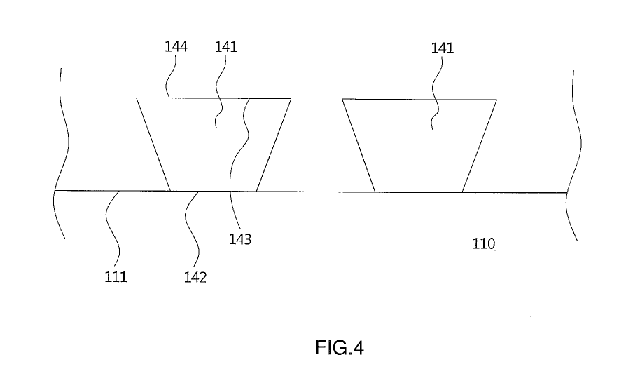

Please refer to FIG. 2 to FIG. 6. FIG. 2 to FIG. 6 depict steps of forming the line pattern according to the preferred embodiment of the present invention in sequence. The method of forming the line pattern on the substrate comprises steps as follows. First step is assembling the color filter 110, the liquid crystal layer 120, and the thin film transistor layer 130 of the display panel 100, and then is applying a photoresist layer 140 to the display surface 111 of the color filter 110 as shown in FIG. 2. Wherein, the photoresist layer 140 includes a negative photoresist material. Next step is exposing the photoresist layer 140. During the process of exposure, a mask (not shown in figures) with a predetermined pattern is blocked between a light source and the photoresist layer 140 to allow a predetermined area 146 of the photoresist layer 140, which corresponds to the predetermined pattern of the mask, to be exposed as shown in FIG. 3. When the exposure process is finish, next step is developing the photoresist layer 140 by using developing solution to dissolve an unexposed negative photoresist material, and then an exposed negative photoresist material is left. When the development process is finish, the developed photoresist layer 140 forms a photoresist pattern 141 (corresponds to the predetermined pattern of the mask) on the display surface 111 as shown in FIG. 4.

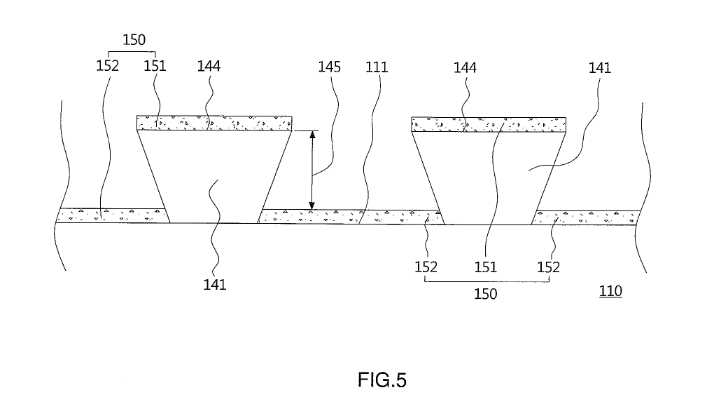

In the embodiment, a cross section of the photoresist pattern 141 includes a bottom edge 142 and a top edge 143. The bottom edge 142 is adjacent to the display surface 111 and is opposite to the top edge 143. A width of the bottom edge 142 is less than that of the top edge 143. Specifically, a shape of the cross section of the photoresist pattern 141 is an inverted trapezoid as a result of characteristics of the negative photoresist material. After the photoresist pattern 141 has been formed on the display surface 111, next step is applying a coating film 150 to the display surface 111. The coating film 150 preferably adopts metal or composite material that has a good electrical conductivity. After the coating film 150 has been applied to the display surface 111, a part of the coating film 150, i.e. the first coating film 151 as shown in FIG. 5, is attached to a top surface 144 of the photoresist pattern 141, and another part of the coating film 150, i.e. the second coating film 152 as shown in FIG. 5, is attached to the display surface 111 between and beside the photoresist pattern 141. Since the cross section of the photoresist pattern 141 is an inverted trapezoid shape, a gap 145 is naturally formed between the first coating film 151 applied to the top surface 144 of the photoresist pattern 141 and the second coating film 152 applied to the display surface 111. The gap 145 corresponds to a thickness of the photoresist pattern 141. Specifically, a height of the gap 145 substantially equals to the thickness of the photoresist pattern 141 minus a thickness of the second coating film 152.

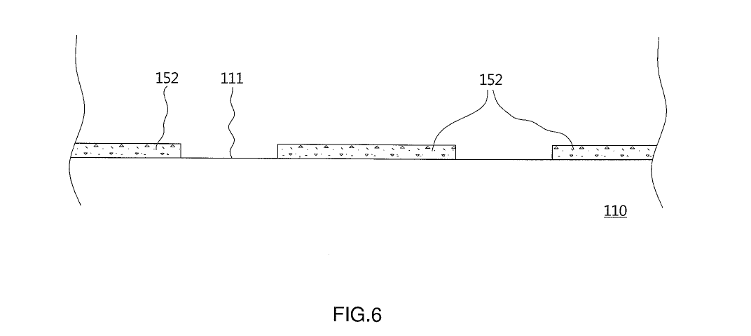

The final step is removing the photoresist pattern 141 by a photoresist stripper. During the step, the photoresist stripper passes through the gap 145, contacts the photoresist pattern 141, and reacts with the photoresist pattern 141. As the photoresist pattern 141 is removed, the first coating film 151 applied to the top surface 144 of the photoresist pattern 141 is removed accordingly, and the second coating film 152 applied to the display surface 111 is left to form the line pattern as shown in FIG. 6. If a shape of the cross section of the photoresist pattern is a trapezoid or a rectangle, the first coating film applied to the top surface of the photoresist pattern may be connected to the second coating film applied to the display surface. In other words, a side of the photoresist pattern is also applied with the coating film, which is against the process of removing photoresist material. The photoresist stripper is easily blocked by the coating film applied to the side of the photoresist pattern. Therefore, the photoresist stripper may be not completely removing the photoresist pattern. In the situation, the yield rate of forming the line pattern may be declines.

In conclusion, the method of forming a line pattern on a substrate that the present invention disclosed can be applied to a touch display device requiring thickness reduction. The method can be performed after a display panel has been assembled to form the line pattern. The method comprises processes of exposure, development, applying a coating film, and removing a photoresist pattern, and doesn't require process of etching. The method prevents negative affection with regard to completeness of the line pattern caused by pollution or scratches on a surface of a substrate plate, since processes thereof do not require etching. And the photoresist pattern can be completely removed because a shape of a cross section of the photoresist pattern of the invention is an inverted trapezoid. Comparing to the prior art, the invention reduces cost and improves yield rate.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of forming a line pattern on a substrate comprising:
providing a substrate plate;
forming a photoresist pattern on a predetermined surface of the substrate plate;
applying a coating film to the predetermined surface of the substrate plate and the photoresist pattern; and
removing the photoresist pattern to form the line pattern.

2. The method of claim 1, wherein steps of forming the photoresist pattern on the predetermined surface of the substrate plate further comprises:
applying a photoresist layer to the predetermined surface;
exposing a predetermined area of the photoresist layer; and
developing the photoresist layer to form the photoresist pattern.

3. The method of claim 2, wherein the photoresist layer includes a negative photoresist material.

4. The method of claim 1, wherein a cross section of the photoresist pattern includes a bottom edge and a top edge, wherein the bottom edge is adjacent to the substrate plate and is opposite to the top edge, and a width of the bottom edge is less than that of the top edge.

5. The method of claim 4, wherein a shape of the cross section of the photoresist pattern is an inverted trapezoid.

6. The method of claim 1, wherein after applying the coating film to the predetermined surface of the substrate plate and the photoresist pattern, a gap is formed between a first coating film applied to the photoresist pattern and a second coating film applied to the predetermined surface, and a height of the gap corresponds to a thickness of the photoresist pattern.

7. The method of claim 1, wherein steps of removing the photoresist pattern to form the line pattern further comprises: using a photoresist stripper to remove the photoresist pattern.

8. The method of claim 1, wherein after removing the photoresist pattern, a first coating film applied to the photoresist pattern is accordingly removed, and a second coating film applied to the predetermined surface is left to form the line pattern.

9. The method of claim 1, wherein the substrate plate includes a color filter, a liquid crystal layer, and a thin film transistor layer, wherein the liquid crystal layer is sandwiched between the color filter and the thin film transistor layer, and the predetermined surface locates on a side of the color filter opposite to the liquid crystal layer.

10. The method of claim 1, wherein the line pattern is a touch sensing component.
